(19) United States
(12) Patent Application Publication
(10) Pub. No.: US 2008/0218191 A1
(43) Pub. Date: Sep. 11, 2008

(54) PROBE ASSEMBLY WITH ROTARY TIP

(75) Inventors: Gunsei Kimoto, Tokyo (JP); Takeshi SAKUMA, Chiba-ken (JP)

Correspondence Address: HAYNES AND BOONE, LLP, 901 Main Street, Suite 3100, Dallas, TX, 75202, US

(73) Assignee: Gunsei Kimoto, Tokyo (JP)

(21) Appl. No.: 12/043,601

(22) Filed: Mar. 6, 2008

(30) Foreign Application Priority Data
Mar. 8, 2007 (JP) 2007-098861

(51) Int. Cl. G01R 1/067

(52) U.S. Cl. 324/762

(57) ABSTRACT

A probe which is cleaning-free, of which rubbing operation can be precisely controlled, and can be used for narrow-pitch pads, is provided. The probe assembly includes: a Z-deforming portion elastically deformable at least in a vertical direction; a tip contact element which includes a contact portion having a curved section, the tip contact element being connected to and supported on an end of the Z-deforming portion via an arm member, the contact portion being made to contact with an electrode pad and is vertically displaceable and rotatable; and a stopper for restricting movement of the tip contact element. After the tip contact element is rotated, due to pushing force from the electrode pad, for a certain distance in a direction of rotation, the stopper controls the movement of the tip contact element to prevent further rotation and to allow vertical movement.

### BACKGROUND OF THE INVENTION

1. Field of the Invention

The present invention relates to a probe assembly (a contact assembly) used for inspecting circuits on plural semiconductor chips formed on a wafer in a production process of an electronic device such as LSI. More particularly, the present invention relates to a probe assembly mounted on a probe card used for inspecting the circuits on a wafer basis. In the circuit inspection, probes, i.e., contacts, are made to contact with electrode pads arranged on a chip to provide electrical conduction collectively between the probes and the chips.

2. Description of Prior Art

As semiconductor technology advances, electronic devices have become more highly integrated, and electrode pads on each wafer chip have also increased in number. Pads have become more precisely arranged, whereby pad areas become smaller and pad pitches becomes narrow. Also, a chip size package (CSP) system becomes dominant in which a bear, non-packaged chip is mounted on a circuit board or other substrate. Under such circumstances, characteristics and quality of the chips must be checked at the wafer level.

Problems arising from the refined, narrow-pitched pad arrangement include that the probe structure should correspond to the precise pad arrangement to provide electrical conduction between the probe and the chip pad for electrical characteristics testing or circuit inspection of electronic devices. Various means have been used for measuring these refined pad arrangements.

Usually, pads on an IC chip to be inspected are formed of aluminum alloy film or gold plate. A pad surface is covered with, for example, an oxide film. After the probe tip is made to contact with the pad, the probe tip is further pushed (i.e., “overdriven”) in the vertical direction for a certain distance. At the same time, the probe tip rubs against the pad surface in the horizontal direction to destroy the oxide film, thereby providing reliable conduction between the probe and the pad.

The aluminum alloy is 20 nm thick, which covers aluminum layer therebelow. Aluminum debris usually adheres to the probe that reached the aluminum layer through the aluminum alloy due to the rubbing operation. The debris is known to get oxidized and become an aluminum alloy, functioning as an insulating material. As a result, the probe can be used for limited times, and the dust or debris must be removed from (i.e., cleaned off) the probe at certain intervals in a place away from the inspection site.

Such a cleaning process may reduce operation rates of the inspection apparatus or decreases inspection reliability.

To address these problems, the inventors have proposed some probe pin structures, which are described in Japanese Patent Application Laid-Open (JP-A) Nos. 2004-274010 and 2005-300545.

Referring to FIGS. 15A and 15B, a conventional probe assembly proposed by the present inventors will be described. FIGS. 15A and 15B illustrate an operation of a conventional probe. FIGS. 16A to 16C illustrate in detail an operation of a tip contact element.

As shown in FIG. 15A, the probe has a link structure with a parallel spring 20, a vertical probe portion 21, and a fixed end 22, altogether forming a Z-deforming portion. A tip contact element 24 with a rotation center 23 is connected serially to the vertical probe portion 21. The tip contact element 24 is made to contact with a surface of a pad 25 to provide electrical conduction therebetween.

In FIG. 15A, parallel beams 20a and 20b are kept in their horizontal positions until relative displacement occurs between the pad 25 and the tip contact element 24 to move the pad 25 vertically to contact with the tip contact element 24. Then, as shown in FIG. 15B, after the pad 25 begins contacting with the probe tip and the pad 25 is vertically overdriven for a certain distance, the parallel beams 20a and 20b rotate to move substantially in parallel to each other. Thus, the vertical probe portion 21 is moved in the vertical direction. At this time, the vertical probe portion 21 is moved in the vertical direction while being moved slightly in the horizontal direction. These travel distances may be determined by selected length, thickness, opening area, and spring constant of material, of the beams.

Along with the movement of the vertical probe portion 21, the tip contact element 24 is moved in the vertical and horizontal directions. As the pad 6 is overdriven, the tip contact element 24 rotates clockwise about the rotation center 23. The operation of the tip contact element 24 in this process will be described in detail with reference to FIGS. 16A to 16C.

FIGS. 16A to 16C illustrate the contact area of the tip contact element and the overdriven pad with the center line of the tip contact element shown as a three-stage trajectory. The operation of the Z-deforming portion is to be considered as fixed, and is not shown in the drawings.

In FIGS. 16A to 16C, reference numeral 27 denotes a part of the probe tip near the contact area with a pad surface 26, and reference numeral 28 denotes the center line of the tip contact element. FIG. 16A shows that the probe has just begun contacting with the pad 26 where the probe tip 27 contacts with the pad surface 26 at a position 27a. After the pad is overdriven to lift the probe tip 27 to the state shown in FIG. 16B, the tip contact element begins to rotate about a rotation center 29. At this moment, the contact point of the probe tip and the pad 26 is shifted from 27a to 27b. After the pad is further overdriven to lift the probe tip 27 to the state shown in FIG. 16C, the tip contact element further rotates and the contact point is shifted from 27b to 27c. Here, as the pad is overdriven, the rotation center is shifted from 29a to 29b, and to 29c. In addition, the unillustrated Z-deforming portion is also displaced.

In this operation, relative displacement of the pad surface 26 and the probe tip 27 occurs due to the rubbing movement. The oxide film is removed at the beginning of contact, e.g., when the contact point is shifted from 27a to 27b, and electrical conduction may be provided at the latter half of the contact, e.g., when the contact point is shifted from 27c to 27d. When the inspection is completed and the pad and the probe are released from pressure, the oxide film or other contaminant material may adhere to the probe tip. The material can be removed at a subsequent inspection event, where the similar rubbing operation is repeated. In this manner, a cleaning-free probe assembly can be provided.

It is significantly difficult, however, to only remove the thin oxide film to expose the pad surface. The rubbing operation abrades not only the oxide film but also the pad material deeply, and thus the pad surface may be damaged. As a result, connection failure may be caused in a subsequent wire bonding process. Electronic circuits formed in a lower part of the pad may also be damaged. In addition, if the probe tip is left for a long time with debris of the abraded pad, such as aluminum, adhering to the probe tip, the adhering material may become oxidized and firmly adhere to the probe tip that cannot be removed at the subsequent rubbing operation for inspection.

In view of the aforementioned, an object of the invention is to provide a probe which provides reliable electrical connection and is cleaning-free with a configuration that the oxide film is removed by precisely controlled rubbing operation with damage to the pad being minimized, and an adhesive material such as the removed oxide film is cleaned off the probe immediately before or after the inspection.

### SUMMARY OF THE INVENTION

A first aspect of the invention is a probe assembly which includes: a Z-deforming portion elastically deformable at least in a vertical direction; a tip contact element which includes a contact portion having a curved section, the tip contact element being connected to and supported on an end of the Z-deforming portion via an arm member, the contact portion being made to contact with an electrode pad and is vertically displaceable and rotatable; and a stopper for restricting movement of the tip contact element. After the tip contact element is rotated due to pushing force from the electrode pad for a certain distance in a direction of rotation, the stopper controls the movement of the tip contact element to prevent further rotation and to allow vertical movement.

A second aspect of the invention is a probe assembly which includes: a Z-deforming portion elastically deformable at least in a vertical direction; a tip contact element which includes a contact portion having a curved section, the tip contact element being connected to and supported on an end of the Z-deforming portion via an arm member, the contact portion being made to contact with an electrode pad and is vertically displaceable and rotatable; a cleaning sheet which can be made to contact with the contact portion of the tip contact element at a contact surface that is a rough surface; and a means for causing rubbing operation due to relative displacement between the tip contact element and the rough surface. The rough surface of the cleaning sheet contacts, in whole or in part, with an area where the cleaning sheet and the electrode pad contact with each other. Rubbing operation is caused due to relative displacement between the tip contact element and the rough surface, along with the rotation of the tip contact element.

According to the first aspect of the invention, since the stopper is provided for controlling the movement of the tip contact element to prevent further rotation and to allow vertical movement after the tip contact element is rotated due to pushing force from the electrode pad for a certain distance in a direction of rotation, the rubbing amount can be controlled to be enough for removing the oxide film on the pad surface. Thereafter, since only pushing force in the z direction acts on the probe, the contact pressure between the probe and the pad surface increases, while the contact resistance therebetween decreases. As a result, more reliable electrical conduction can be established.

According to the second aspect of the invention, since a cleaning sheet having a rough surface for contacting with the tip contact element is provided, and the rough surface of the cleaning sheet contacts, in whole or in part, with an area where the cleaning sheet and the electrode pad contact with each other, and rubbing operation is caused due to relative displacement between the tip contact element and the rough surface, along with the rotation of the tip contact element, the cleaning sheet can remove the materials adhering to the tip contact element immediately after the completion of the inspection in the process that the inspection is completed and the pad and the probe are released from pressure.

Therefore, an object of the invention is to provide a probe which provides reliable electrical connection and is cleaning-free with a configuration that the oxide film is removed by precisely controlled rubbing operation with damage to the pad being minimized, and an adhesive material such as the removed oxide film is cleaned off the probe immediately before or after the inspection.

The above described object and advantages of the invention will become apparent in the following description with reference to the accompanying drawings.

### BRIEF DESCRIPTION OF THE DRAWINGS

FIG. 1 illustrates a probe assembly according to a first embodiment of the invention;

FIGS. 2A and 2B schematically illustrate a general operation of the probe assembly;

FIGS. 3A and 3B illustrate a general operation of the probe assembly according to the first embodiment;

FIGS. 4A to 4D illustrate in detail an operation of a probe tip contact element according to the first embodiment;

FIG. 5 shows changes in state as the operation proceeds in the first embodiment of the invention;

FIGS. 6A and 6B illustrate a general operation of a probe in a second embodiment;

FIG. 7 illustrates the second embodiment of the invention;

FIGS. 8A to 8C illustrate in detail an operation of a probe tip contact element according to the second embodiment;

FIGS. 9A and 9B illustrate in detail an operation of a probe tip contact element according to a third embodiment;

FIG. 10 is a side view of a film-laminated probe according to a fourth embodiment of the invention;

FIG. 11 is an assembly view of the film-laminated probe according to b the fourth embodiment of the invention;

FIGS. 12A to 12D illustrate in detail an operation of a probe tip contact element according to a fifth embodiment;

FIGS. 13A to 13C illustrate in detail an operation of a probe tip contact element according to a sixth embodiment;

FIGS. 14A to 14D illustrate in detail an operation of a probe tip contact element according to a seventh embodiment;

FIGS. 15A and 15B illustrate a probe assembly according to a conventional embodiment; and

FIGS. 16A to 16C illustrate in detail an operation of the conventional embodiment.

### DETAILED DESCRIPTION OF THE PREFERRED EMBODIMENTS

Hereinafter, preferred embodiments of the invention will be described with reference to the accompanying drawings. It should be noted that the invention is not limited to these embodiments.

### First Embodiment

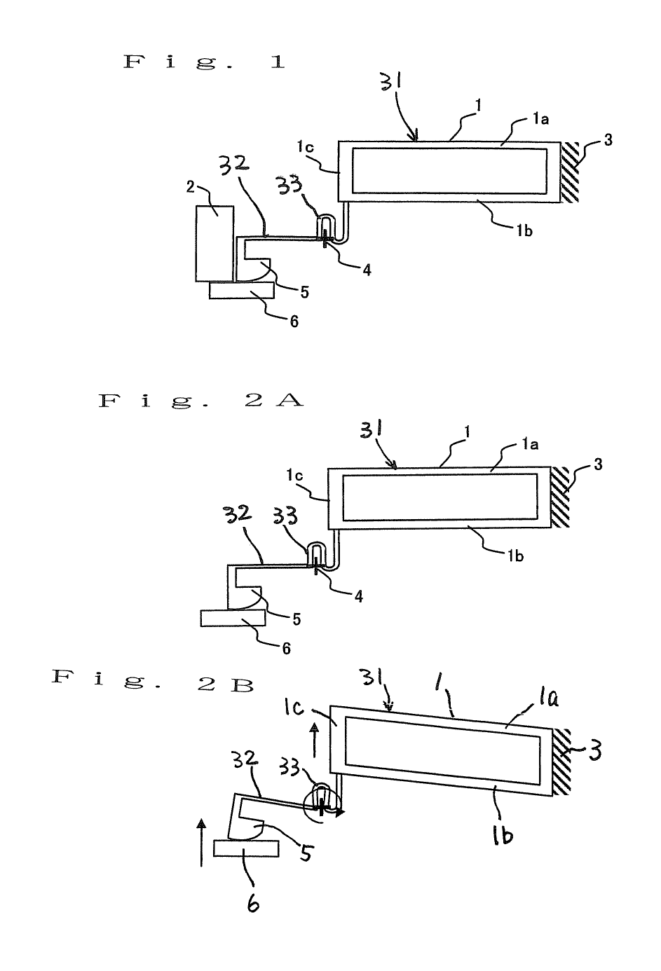

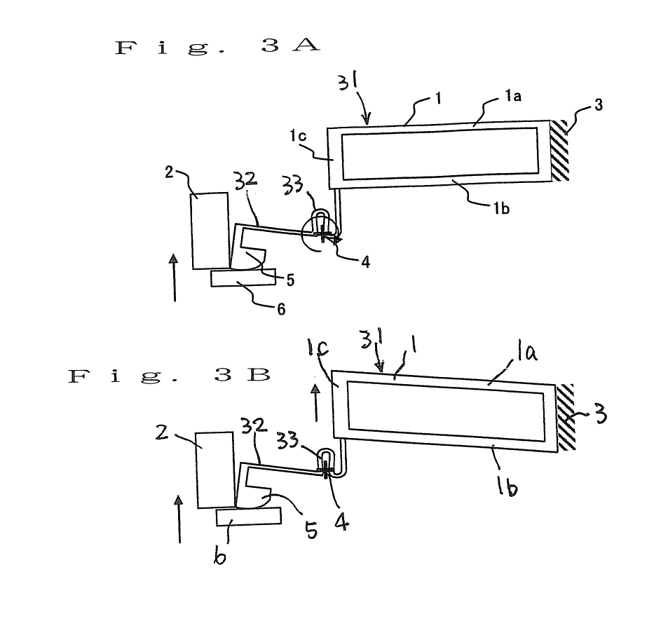

FIG. 1 is a side view of a probe assembly according to a first embodiment of the invention. FIGS. 2A, 2B, 3A and 3B are side views illustrating the general operation of the present probe.

As shown in FIG. 1, the probe has a link structure with a parallel spring 1. Upper and lower sides of the link structure are parallel beams 1a and 1b, respectively. An end of the link structure is formed as a vertical probe portion 1c, and a base end portion of the link structure is formed as a fixed end 3. These components altogether form a Z-deforming portion 31. A support arm 32 is provided to extend from the vertical probe portion 1c. The support arm 32 includes a tip contact element 5 at an end thereof, and a displacement absorbing portion 33 in a middle area thereof. In the example of FIG. 1, the displacement absorbing portion 33 is formed in an inverted U-shape, but it may alternatively be formed in a U-shape. When the tip contact element 5 is displaced (moved) vertically, the displacement absorbing portion 33 allows the tip contact element 5 to rotate. A rotation center 4 is provided by the displacement absorbing portion 33. The tip contact element 5 functions as a probe terminal with one end thereof contacting with a surface of a pad 6 to provide electrical conduction between the tip contact element 5 and the pad 6. The tip contact element 5 has a curved configuration with a circular or elliptic section, not a needle configuration. When the tip contact element 5 is made to contact with the pad 6 and moved vertically, the tip contact element 5 rotates (or rolls) with respect to the pad 6. In the present embodiment, the tip contact element 5 is described to have a curved section, but the shape of the tip contact element 5 is not limited to the same.

A stopper 2 is provided in the vicinity of the tip contact element 5 in the rotating direction thereof. After the tip contact element 5 rotates beyond a certain distance, the stopper 2 prevents further rotation, but allows vertical movement, of the tip contact element 5.

Referring to FIGS. 2A and 2B, a general operation of the thus-structured probe assembly will be described. In FIG. 2A, parallel beams 1a and 1b of the probe are kept in their horizontal positions until relative displacement occurs between the pad 6 and the tip contact element 5. The relative displacement moves the pad 6 vertically and makes it contact with the tip contact element 5. Then, as shown in FIG. 2B, after the pad 6 begins contacting with the tip contact element 5 and the pad 6 is vertically overdriven for a certain distance, the parallel beams 20a and 20b rotate to move substantially in parallel to each other. Thus, the vertical probe portion 1c is moved in the vertical direction.

Along with the movement of the vertical probe portion 1c, the tip contact element 5 is moved in the vertical and horizontal directions. As the pad 6 is overdriven, the tip contact element 1c begins to rotate clockwise about the rotation center 4.

The travel distance of the parallel spring 1 and the tip contact element 5 due to the overdriven pad 6 may be determined by optionally-selected length, width thickness, opening area, and spring constant of material, of the beams. In the present embodiment, the operation is optimized when the rigidity of the tip contact element 5 is smaller than that of the parallel spring 1. Such an operation will be described with reference to FIG. 3.

In the present embodiment, the rigidity of the tip contact element 5 is smaller than that of the parallel spring 1. As shown in FIG. 3A, after the pad 6 is made to contact with the tip contact element 5 and is overdriven, the rotation of the tip contact element 5 becomes dominant. The tip contact element 5 continues rotating without following significant displacement of the parallel spring 1. After rotating for a certain distance, the tip contact element 5 abuts on the stopper 2 and stops rotating. After the pad 6 is further overdriven, then a z-direction deformation of the parallel spring 1 becomes dominant.

In the foregoing description, as shown in FIGS. 1 to 3, the Z-deforming portion 31 is formed by the parallel spring 1 with two parallel beams 1a and 1b. However, the object of the invention may also be achieved with a simple one-beam cantilever configuration (not shown). In such a one-beam cantilever configuration, the rotational movement is applied in the z direction.

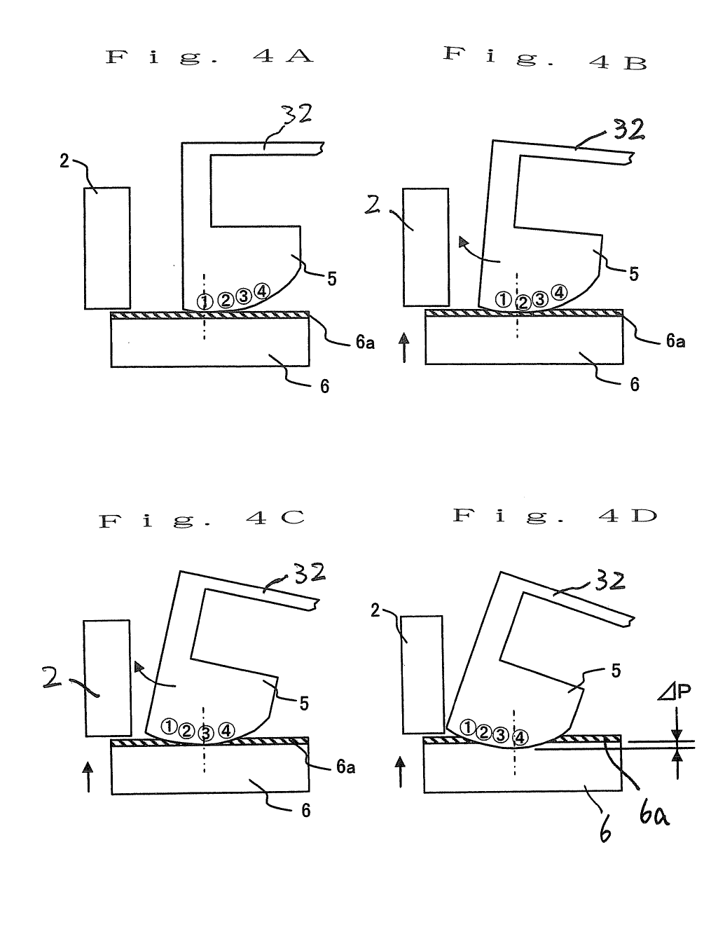

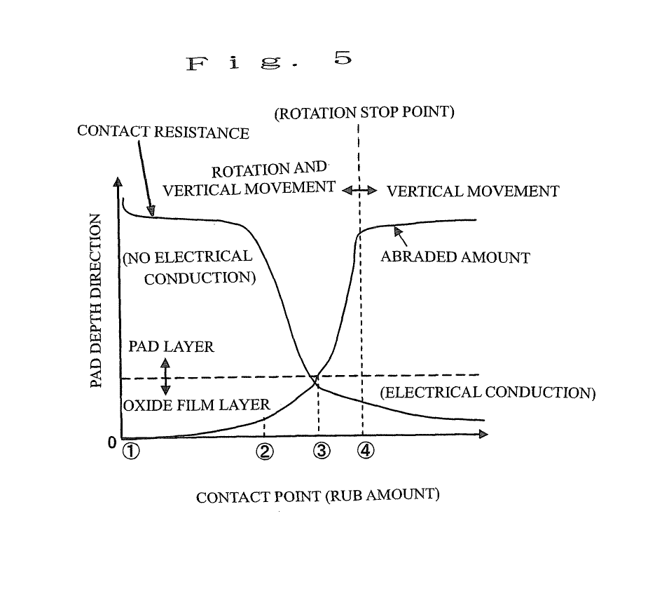

The general operation of the probe was described above. The operation of the tip contact element 5 around the contact area will be described in detail hereinbelow. FIGS. 4A to 4D illustrate in detail the operation around the tip contact element 5. FIG. 5 shows change in an abraded amount on the pad surface and the contact resistance as the probe operation progresses.

In FIG. 4A, the tip contact element 5 has begun contacting with the pad 6 at contact point (1). Reference numeral 6a denotes a portion of the pad surface expanded in a direction of the thickness of the oxide film. After the pad 6 is overdriven to lift the tip contact element 5 of the probe to the position shown in FIG. 4B, the tip contact element 5 is rotated such that the contact point is shifted from (1) to (2). At this moment, the oxide film 6a is abraded in the contact area, but the contact resistance in the contact area is still large as shown in FIG. 5, and no electrical conduction is established in this state.

After the pad 6 is further overdriven to lift the tip contact element 5 to the position shown in FIG. 4C, the tip contact element 5 is further rotated such that the contact point is shifted from (2) to (3). Given that the oxide film 6a is abraded to the pad surface, as shown in FIG. 5, the contact resistance reduced significantly and electrical conduction is established. Since the oxide film is a thin film of, for example, aluminum oxide (Al₂O₃) and the contact area of the tip contact element 5 is curved, the pad surface should be precisely abraded to obtain the area to be removed to provide electrical conduction.

FIG. 4D shows a state in which the contact area of the tip contact element 5 with the pad 6 has been shifted from (3) to (4), and the tip contact element 5 has abraded the pad surface by an amount of ΔP. At this moment, as shown in FIG. 5, the contact resistance is small enough to establish electrical conduction between the tip contact element 5 and the pad 6.

After the contact point of the tip contact element 5 and the pad 6 reaches (4), the stopper 2 is positioned so as to prevent further rotation of the tip contact element 5. Thereafter, as shown in FIG. 3B, only vertical force acts on the pad 6 and, as shown in FIG. 5, the contact resistance is further reduced to provide more reliable electrical conduction.

The contact points (3) and (4) may be determined by using sample products or the like.

### Second Embodiment

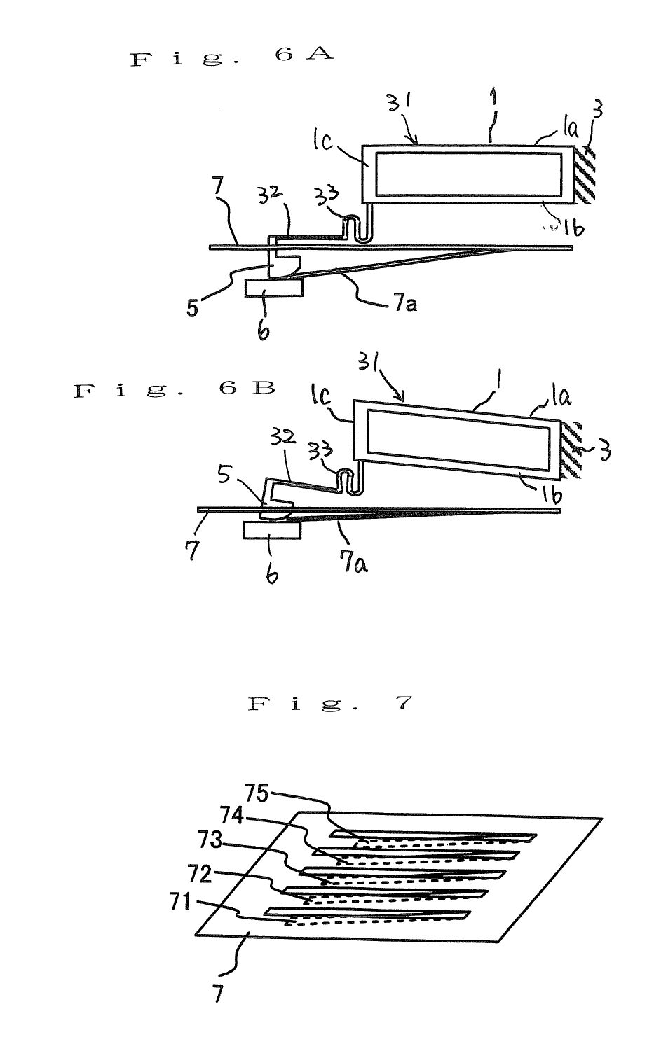

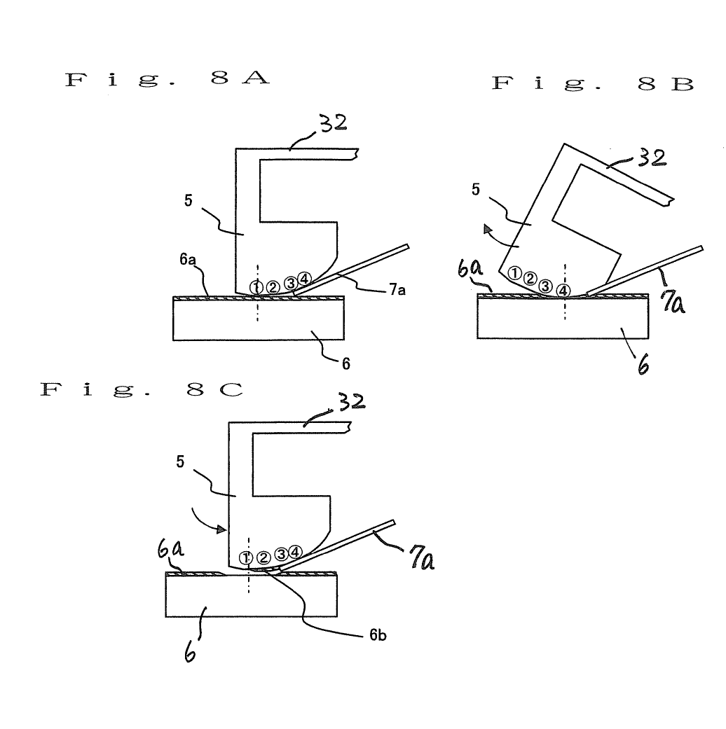

FIGS. 6A, 6B and 7 illustrate a probe assembly according to a second embodiment of the invention. FIGS. 8A to 8C illustrate operation of the present embodiment. In FIGS. 6A and 6B, a cleaning sheet 7 is disposed with a rough surface 7a contacting with the tip contact element 5. An exemplary structure of the cleaning sheet 7 is shown in FIG. 7, which may be obtained in the following manner. In a resin sheet, openings are provided through which probes are to be inserted. A cantilever cleaning sheet 71 is provided on one side of the opening. Fine particles such as diamond particles are applied to the surface of the cleaning sheet 7 where it abuts the tip contact element 5. The cleaning sheet 7 is disposed such that an end of the rough surface 7a abuts a portion of the tip contact element 5. As the tip contact element 5 rotates, the tip contact element 5 and the rough surface 7a are displaced relatively, and rub against each other.

Referring to FIGS. 8A to 8C, the operation of the second embodiment will be described in detail. In FIG. 8A, the tip contact element 5 has begun contacting with the pad 6 at contact point (1). Reference numeral 6a denotes the oxide film formed on the pad surface. After the pad 6 is overdriven to lift the tip contact element 5 of the probe to the position shown in FIG. 8B, the tip contact element 5 is rotated such that the contact point of the tip contact element 5 and the pad 6 is shifted sequentially from (1) to (4) in the manner as shown in FIGS. 4A to 4D. Electrical conduction is established between the tip contact element 5 and the pad 6 when they are made to contact with each other at the point (4) and thus inspection may be conducted. In this process, the oxide film 6a and a part of the pad material are abraded.

FIG. 8C illustrates a state in which the inspection is completed and the pushing force is released. In this state, the tip contact element 5 has returned to its original position. Part of the oxide film and the pad material 6a adhere to the contact points (1) to (4) of the released tip contact element 5. In the process of releasing the tip contact element 5, the rough surface 7a rubs against the tip contact element 5 and the adhesive material at least near the points (3) and (4) are removed where the electrical contact is mainly provided.

In this manner, after the inspection is completed and the pushing force on the pad and the probe is released to return them to their original positions, even if contaminant materials such as the oxide film adhere to the probe tip, the adhesive material can be removed immediately after the release of the pressure, and the contact surface may be kept clean for subsequent inspection events. Thus, a cleaning-free probe that provides sufficient electrical contact can be obtained.

### Third Embodiment

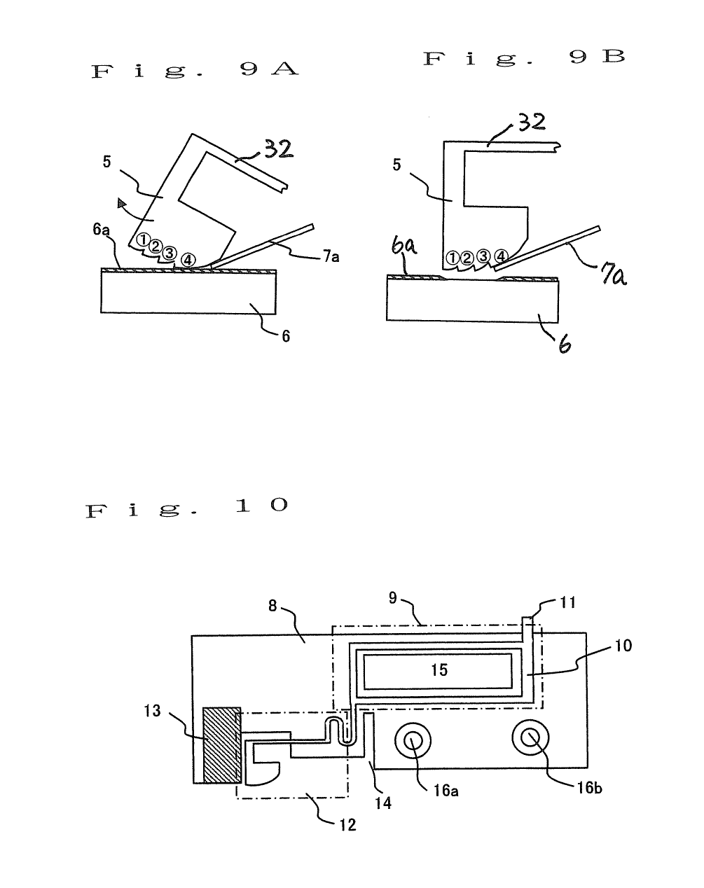

FIGS. 9A and 9B illustrate a tip contact element of a probe according to a third embodiment of the invention. The tip contact elements of the first and second embodiments may also be serrated as shown in FIGS. 9A and 9B. The serrated shape, in combination with a rigidity design, of the tip contact element promotes destroying the oxide film. With this structure, a more preferred rubbing amount may be determined.

### Fourth Embodiment

In order to implement the foregoing embodiments, a structure for precisely controlling the probe tip is required. An embodiment in which the invention is applied to a film-laminated probe assembly that has been proposed by the present inventors will be given as a fourth embodiment. As shown in JP-A Nos. 2004-274010 (especially FIG. 24) and 2005-300545 (especially FIG. 1), such a film-laminated probe assembly is provided by bonding a copper film onto a surface of a ribbon-shaped or strip-shaped resin film, etching the copper film to form a copper probe with a curved portion on the resin film surface, and then laminating plural sheets of the resin film in which the probe is formed.

FIG. 10 shows an exemplary structure of a film-laminated probe assembly. As shown in FIG. 10, a copper (e.g., beryllium copper) film is bonded onto a resin (e.g., polyimide resin) film 8, and then the copper film is etched to form a Z-deforming potion 9, a conductive portion 10, a signal line terminal portion 11, and a tip contact element 12. A stopper 13 is formed by printed insulating resin. The resin film 8 has an opening 14, cutout 15, and holes 16a and 16b in advance.

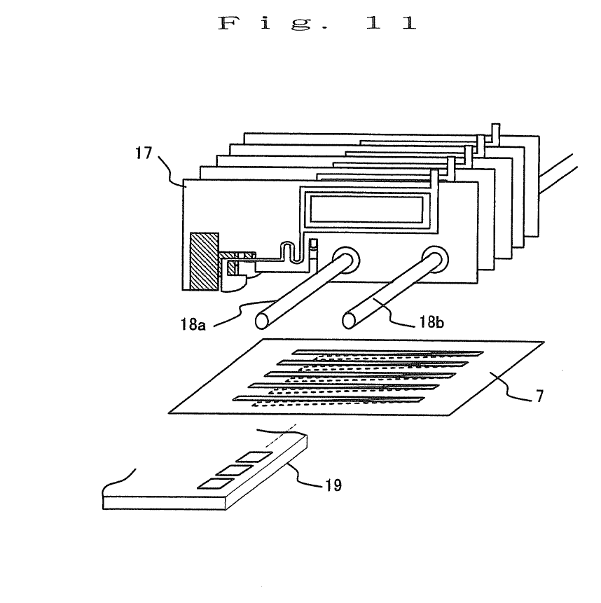

FIG. 11 shows a probe assembly formed by stacking plural film-laminated probes 17. N film-laminated probes 17 are stacked with support rods 18a and 18b inserted into the holes 16a and 16b, respectively. With this structure, n pads having a pitch corresponding to the film thickness (several tens of microns) can be inspected at one time. This embodiment may also be applied to pads arranged in, for example, a zigzag pattern with individually-selected wiring pattern of the film-laminated probes 17, a position of the probe tip 12, and a position of the signal line terminal portion 11. Further, in the present embodiment, the position of the signal line terminal portion may be determined to correspond to the position of signal input/output terminals of a printed-wiring board of an inspection apparatus.

The cleaning sheet 7 described in the second embodiment is disposed between the probe and chips 19 to be inspected to implement the invention.

### Fifth Embodiment

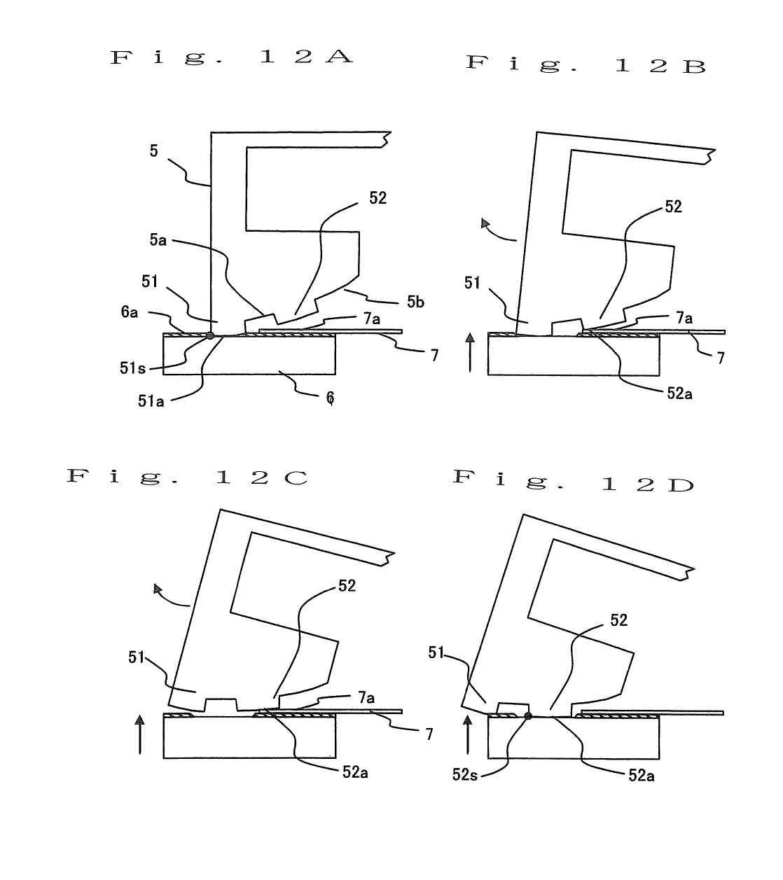

FIGS. 12A to 12D illustrate a probe tip contact element according to a fifth embodiment of the invention. As shown in FIGS. 12A to 12D, a tip contact element 5 includes cutouts 5a and 5b in an area where it contacts with a pad surface. The cutouts 5a and 5b divide the curved contact surface into a first curved portion 51 and a second curved portion 52. A cleaning sheet 7 is provided in advance on a surface of a pad 6 with a rough surface 7a facing upward.

In the process that the pad 6 is vertically moved and the tip contact element 5 is rotated, the pad 6 may push the curved surface of the tip contact element 5 directly, or alternatively, the pad 6 may push the curved surface of the tip contact element 5 via the cleaning sheet 7. As the tip contact element 5 rotates with the first curved portion 51 contacting with the pad 6, the pad 6 and the first curved portion 51 become out of contact at a right end of the first curved portion 51. At this moment, pushing force is transmitted to the second curved portion 52 via the cleaning sheet 7. Thus, transmission of the pushing force is shifted from the first curved portion to the second curved portion.

In order to continue the rotation of the tip contact element 5 until the first curved portion 51 is made to contact directly with the pad, a contact start point 51s of the first curved portion 51 in FIG. 12A and a contact start point 52s of the second curved portion 52 in FIG. 12D need to be located at the same position on the electrode pad.

The operation of the probe tip contact element according to the present embodiment will be described in detail below. In FIG. 12A, the tip contact element 5 has begun contacting with the pad 6. After the pad 6 is overdriven to lift the tip contact element 5 of the probe to the position shown in FIG. 12B, the first curved portion 51 is rotated such that a contact point 51a of the tip contact element 5 and the pad 6 is shifted accompanying rub operation. In this process, the oxide film 6a and a part of the pad material of aluminum are abraded to provide an area where electrical conduction can be provided.

As the first curved portion 51 is moved and the contact point 51a reaches a right end of the first curved portion 51, the left end of the second curved portion 52 reaches the rough surface 7a of the cleaning sheet 7. At this moment, transmission of the pushing force is shifted from the first curved portion to the second curved portion at the contact point 52a.

In the process that the pad 6 is further overdriven to lift the tip contact element 5 of the probe to the position shown in FIG. 12C, the second curved portion 52 rubs against the rough surface 7a of the cleaning sheet 7 to remove the contaminant material and the oxide film adhering to the second curved portion 52.

After the tip contact element 5 is further rotated and the second curved portion 52 comes out of the cleaning sheet 7, as shown in FIG. 12D, the second curved portion 52 reaches the area of the pad where the oxide film 6a and a part of the pad material have been removed. In this state, electrical conduction may be established between the tip contact element 5 and the pad 6 via the second curved portion 52.

The above-described configuration includes a single first curved portion for removing the oxide film on the pad. To reliably remove the oxide film, however, n−1 first curved portions may be provided by dividing the tip contact element into n curved portions. In this case, the above-described operation is applied to at least n−1 th first curved portion.

### Sixth Embodiment

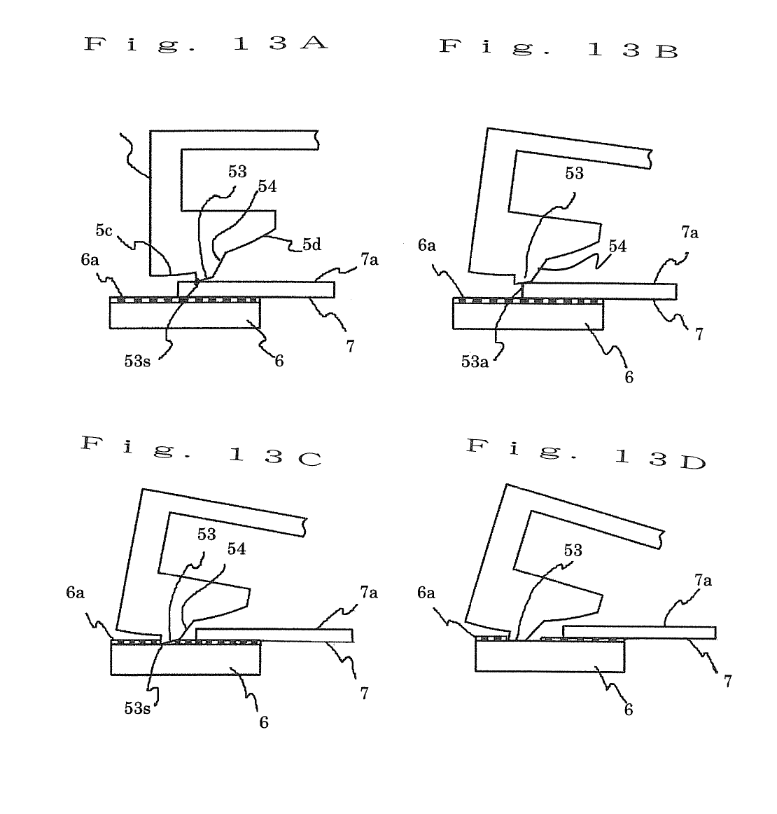

FIG. 13 illustrates a probe tip contact element according to a sixth embodiment of the invention. The present embodiment is simply structured, permitting use of a thick cleaning sheet. Only thin cleaning sheet may be used in the fifth embodiment, because the difference in level in the z direction between the first contact curved portion and the second contact curved portion with reference to the pad surface is small. In the sixth embodiment, a single contact curved portion is employed and the cleaning sheet is inserted between the pad and the contact curved portion. With this configuration, a cleaning sheet of any thickness may be used.

As shown in FIG. 13, cutouts 5c and 5d are provided at an end of a tip contact element 5. The present embodiment is provided by removing one of the two contact curved portions of the fifth embodiment. Thus, cutouts 5c and 5d are provided.

The contact surface 53 has a slope section 54 at the side of the cutout 5d. A cleaning sheet 7 is provided in advance on a surface of a pad 6 with a rough surface 7a facing upward.

In the process that the pad 6 is vertically moved and the tip contact element 5 is rotated, the pad 6 may push the curved surface of the tip contact element 5 via the cleaning sheet 7, or alternatively, the pad 6 may push the contact curved surface 53 of the tip contact element 5 directly. As the tip contact element 5 rotates with the contact surface 53 contacting with the pad 6 via the cleaning sheet 7, the pad 6 and the contact surface 53 become out of contact at a right end of the contact surface 53. At this moment, pushing force is transmitted to the slope section 54 via the cleaning sheet 7. Thus, transmission of the pushing force is shifted from the contact surface 53 to the slope section 54.

In order to rotate the tip contact element 5 until the contact surface 53 is made to contact directly with the pad, the contact sheet 7 should be moved against the slope section 54 shown in FIG. 13C and a contact start point 53s of the contact surface 53 are located at the same position.

The operation of this embodiment is as follows. FIG. 13A illustrates a state in which the pad 6 begins contacting with the probe tip 5 via the cleaning sheet 7. After the pad 6 is overdriven to lift the tip contact element 5 of the probe to the position shown in FIG. 13B, the contact surface 53 is rotated such that the contact start point 53s on the contact surface 53 is moved while rubbing against the rough surface 7a of the cleaning sheet 7. In the course of movement of the contact surface 53, contaminant material and oxide film adhering to the contact surface 53 are removed.

As the contact surface 53 is moved, when the contact point 53a reaches the right end of the contact surface 53, the left end of the slope section 54 is positioned on the rough surface 7a of the cleaning sheet 7. At this moment, transmission of the pushing force is shifted from the contact surface 53 to the slope section 54.

In the process that the pad 6 is further overdriven to lift the tip contact element 5 of the probe to the position shown in FIG. 13C, when the slope section 54 is moved away from the cleaning sheet 7, the contact start point 53s of the contact surface 53 is made to contact with the pad 6. The contact surface 53 rubs or wipes against the pad 6 such that the oxide film 6a and a part of the pad material of aluminum are abraded to provide an area where electrical conduction can be provided. After the tip contact element 5 is further rotated, as shown in FIG. 13D, the contact surface 53 is in whole or in part made to contact with the pad 6 where the oxide film 6a or the part of the pad material have been removed, thereby permitting electrical conduction between the tip contact element 6 and the pad 6 via the contact surface 53.

### Seventh Embodiment

A tip contact portion of a probe of a seventh embodiment is formed as a sharp projection, and the operation thereof will be described.

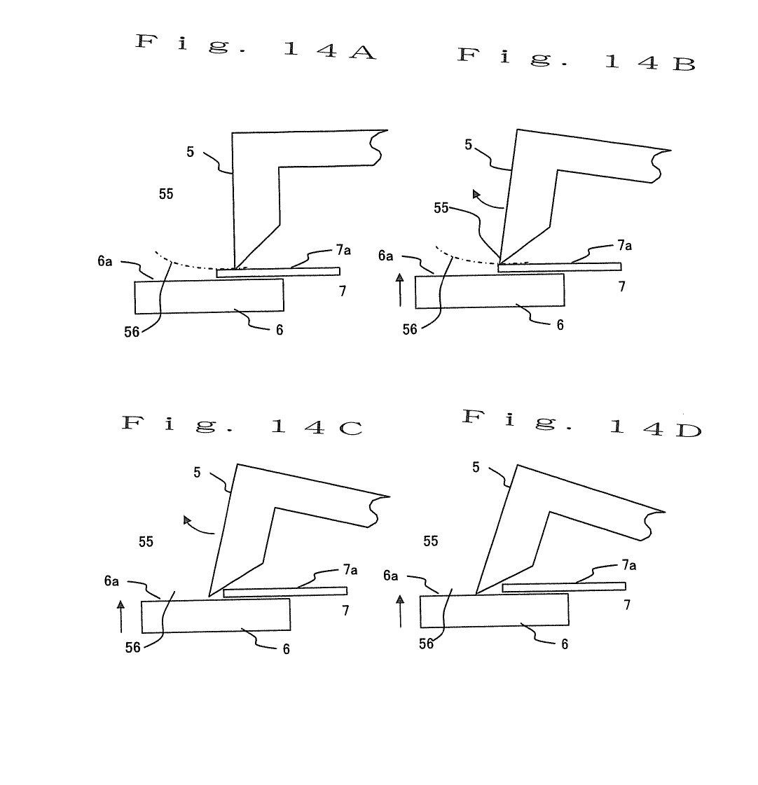

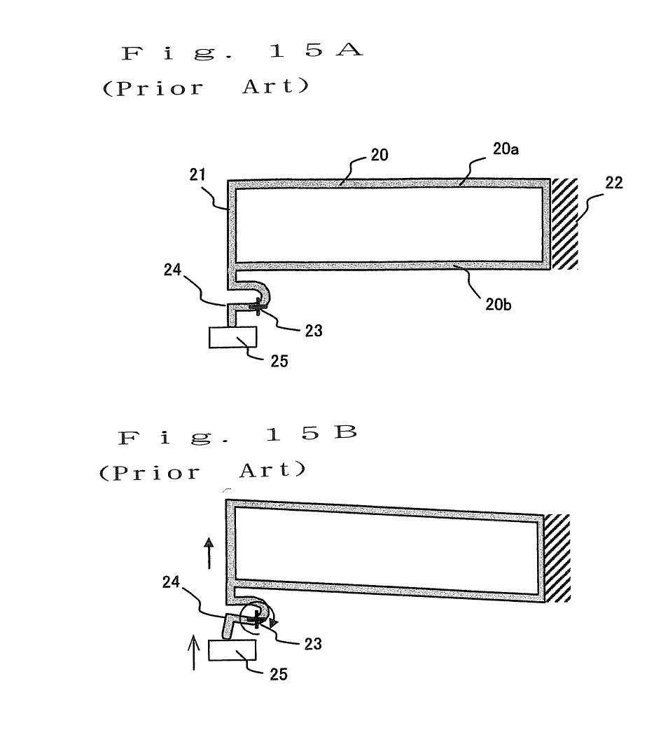

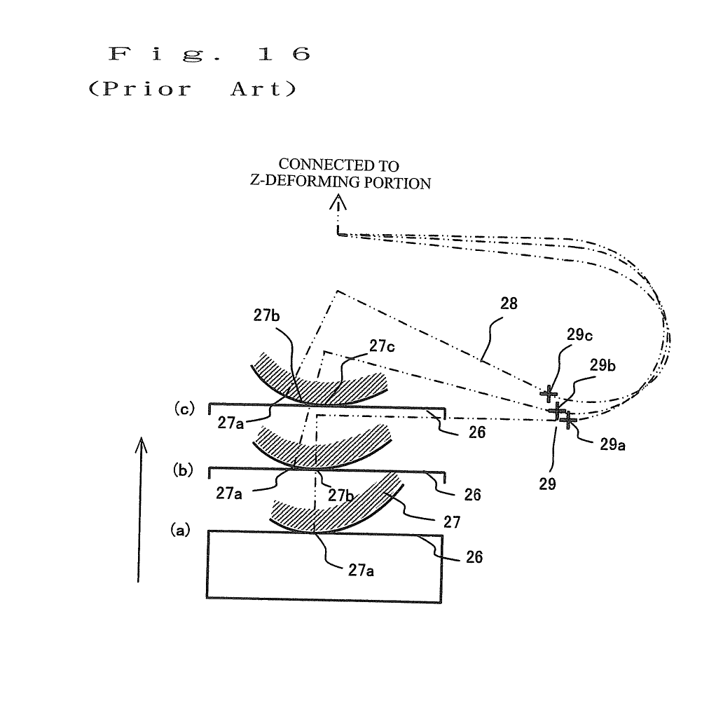

FIGS. 14A to 14D illustrate the present embodiment, in which a tip contact portion 55 of a contact portion 5 has an angle of substantially 30 to 45 degrees. The tip contact portion 55 rotates along a rotation curve 56 as a pad 6 is overdriven. As in the sixth embodiment, a cleaning sheet 7 is provided in advance on a surface of a pad 6 with a rough surface 7a facing upward.

The operation of this embodiment is as follows. FIG. 14A illustrates a state in which the pad 6 begins contacting with the probe tip 5 via the cleaning sheet 7. After the pad 6 is overdriven to lift the tip contact element 5 of the probe to the position shown in FIG. 14B, the tip contact portion 55 is rotated to be moved while rubbing against the rough surface 7a of the cleaning sheet 7. In the course of movement of the tip contact portion 55, contaminant material and oxide film adhering to the tip contact portion 55 are removed.

As the tip contact portion 55 is further moved, the tip contact portion 55 falls out of the rough surface 7a of the cleaning sheet 7, and reaches the pad surface as shown in FIG. 14C. From now on, the pushing force from the pad 6 is transmitted directly to the tip contact portion 55.

In the process that the pad 6 is further overdriven to lift the tip contact element 5 of the probe to the position shown in FIG. 14D, the tip contact portion 55 rubs against the pad 6 to abrade the oxide film 6a and a part of the pad material of aluminum, thereby providing electrical conduction.

According to the present embodiment, since the tip contact portion 55 is formed as a sharp projection, the rubbing area can be made smaller than that required for a curved contact portion. Also, since the contact area is small, the oxide film can be removed with smaller pushing force to provide electrical conduction.

With the described configuration, the oxide film on the pad can be removed for each inspection event, and the curved portion can be cleaned immediately before inspection in an area where electrical conduction is provided.

According to the probe of the invention, in a circuit inspection apparatus (prober) that can be used for narrow-pitched semiconductor devices, rubbing damage to the pad can be minimized by precisely controlling the rubbing operation of the probe tip. Further, the probe of the invention also provides economic benefits that, since the oxide film on the pad surface and contaminants adhering to the probe tip are removed for each inspecting event, failure in electrical connection can be eliminated and the inspection process is not interrupted for cleaning the probe.

The present invention has been described with reference to the preferred embodiments shown in the drawings. However, it will be apparent to those skilled in the art that various changes and modifications can be made without departing from the spirit of the present invention.

1. A probe assembly comprising:
a Z-deforming portion elastically deformable at least in a vertical direction;
a tip contact element which includes a contact portion having a curved section, the tip contact element being connected to and supported on an end of the Z-deforming portion via an arm member, the contact portion being made to contact with an electrode pad and is vertically displaceable and rotatable; and
a stopper for restricting movement of the tip contact element,
wherein, after the tip contact element is rotated due to pushing force from the electrode pad for a certain distance in a direction of rotation, the stopper controls the movement of the tip contact element to prevent further rotation and to allow vertical movement.

2. A probe assembly comprising:
a Z-deforming portion elastically deformable at least in a vertical direction;
a tip contact element which includes a contact portion having a curved section, the tip contact element being connected to and supported on an end of the Z-deforming portion via an arm member, the contact portion being made to contact with an electrode pad and is vertically displaceable and rotatable; and
a cleaning sheet which can be made to contact with the contact portion of the tip contact element at a contact surface that is a rough Surface,
wherein:
the rough surface of the cleaning sheet contacts, in whole or in part, with an area where the cleaning sheet and the electrode pad contact with each other; and
a means is provided for causing rubbing operation due to relative displacement between the tip contact element and the rough surface, along with the rotation of the tip contact element.

3. The probe assembly according to claim 1, wherein a contact area between the tip contact element and the electrode pad is serrated in whole or in part.

4. The probe assembly according to claim 1, wherein a plurality of cutouts are provided in the contact area between the tip contact element and the electrode pad, the cutouts define a first curved surface and a second curved surface, the first curved surface being used for cleaning in a former part of the contact area, and the second curved surface being used for establishing electrical conduction in a latter part of the contact area.

5. A probe assembly according to claim 4, wherein: n curved surfaces are defined by one or more cutouts in the contact area of the tip contact element and the electrode pad; the probe assembly including a first curved surface where the tip contact element begins contacting with the electrode pad, an n th curved surface, and n−1 th rough surface that serves as a cleaning sheet; force provided by a vertical movement of the pad acts on one of the n th curved surface or the n−1 th curved surface via the cleaning sheet, thereby rotating a probe tip; and rubbing or wiping operation between the directly-contacting probe tip and the electrode pad removes an insulating layer.

6. The probe assembly according to claim 5, wherein the n−1 the curved surface and the n th curved surface contact with the electrode pad at the same position as the tip contact element rotates.

7. The probe assembly of claim 4, wherein the insulating layer is removed through rubbing or wiping operation of the contact surface in whole or in part, after a contact surface that is rotated via the cleaning sheet by the movement of the electrode pad is disengaged from the cleaning sheet.

8. The probe assembly according to claim 1, wherein the tip contact element is formed as a sharp projection.

9. A probe assembly configured as a cantilever which includes a rotary tip contact element provided at an end thereof, and a means for rotating the tip contact element, wherein the tip contact element is formed as a sharp projection.

10. The probe assembly according to claim 9, wherein tip contact element is cleaned with a cleaning sheet.

11. The probe assembly according to claim 2, wherein a contact area between the tip contact element and the electrode pad is serrated in whole or in part.

12. The probe assembly according to claim 2, wherein a plurality of cutouts are provided in the contact area between the tip contact element and the electrode pad, the cutouts define a first curved surface and a second curved surface, the first curved surface being used for cleaning in a former part of the contact area, and the second curved surface being used for establishing electrical conduction in a latter part of the contact area.

13. A probe assembly according to claim 2, wherein: a curved surfaces are defined by one or more cutouts in the contact area of the tip contact element and the electrode pad; the probe assembly including a first curved Surface where the tip contact element begins contacting with the electrode pad, an n th curved surface, and n−1 th rough surface that serves as a cleaning sheet; force provided by a vertical movement of the pad acts on one of the n th curved surface or the n−1 th curved surface via the cleaning sheet, thereby rotating a probe tip; and rubbing or wiping operation between the directly-contacting probe tip and the electrode pad removes an insulating layer.

14. The probe assembly according to claim 13, wherein the n−1 the curved surface and the n th curved surface contact with the electrode pad at the same position as the tip contact element rotates.

15. The probe assembly of claim 2, wherein the insulating layer is removed through rubbing or wiping operation of the contact surface in whole or in part, after a contact surface that is rotated via the cleaning sheet by the movement of the electrode pad is disengaged from the cleaning sheet.

16. The probe assembly according to claim 2, wherein the tip contact element is formed as a sharp projection.
